(19) United States
(12) Patent Application Publication
(10) Pub. No.: US 2025/0118652 A1
(43) Pub. Date: Apr. 10, 2025

(54) SEMICONDUCTOR PACKAGE

(71) Applicant: SAMSUNG ELECTRONICS CO., LTD., Suwon-si (KR)

(72) Inventor: Seunghwan Baek, Suwon-si (KR)

(21) Appl. No.: 18/738,701

(22) Filed: Jun. 10, 2024

(30) Foreign Application Priority Data
Oct. 6, 2023 (KR) 10-2023-0133012

(51) Int. Cl. H01L 23/498; H01L 23/00; H01L 23/538; H01L 25/18; H10B 80/00

(52) U.S. Cl. CPC H01L 23/49838; H01L 23/49833; H01L 23/5386; H01L 24/08; H01L 24/16; H01L 25/18; H10B 80/00; H01L 24/32; H01L 24/48; H01L 24/73; H01L 2224/08225; H01L 2224/16238; H01L 2224/32225; H01L 2224/48225; H01L 2224/73204; H01L 2224/73257; H01L 2924/1431; H01L 2924/1436; H01L 2924/1438

(57) ABSTRACT

An example semiconductor package comprises a lower semiconductor package and an upper semiconductor package. The lower semiconductor package includes a first substrate and a dielectric pattern on a top surface of the first substrate. The first substrate includes first pads. The dielectric pattern includes stepwise openings that expose the first pads. A cross-section of a stepwise opening has a pair of stepwise structures. A stepwise structure includes a first lateral surface, a second lateral surface, and a first bottom surface that connects the first and second lateral surfaces with each other. The first lateral surface is connected with a top surface of a first pad. The second lateral surface is connected with a top surface of the dielectric pattern. The upper semiconductor package includes connection terminals on a lower portion of the upper semiconductor package. The connection terminals are respectively attached to the first pads.

### CROSS-REFERENCE TO RELATED APPLICATION

This application claims priority under 35 U.S.C § 119 to Korean Patent Application No. 10-2023-0133012 filed on Oct. 6, 2023, in the Korean Intellectual Property Office, the disclosure of which is hereby incorporated by reference in its entirety.

### BACKGROUND

A semiconductor package is provided to implement an integrated circuit chip to qualify for use in electronic products. A semiconductor package is typically configured such that a semiconductor chip is mounted on a printed circuit board and bonding wires or bumps are used to electrically connect the semiconductor chip to the printed circuit board. With the development of electronic industry, various studies have been conducted to improve reliability and durability of semiconductor packages.

### SUMMARY

The present disclosure relates to semiconductor packages, including a semiconductor package with improved structural stability.

An object of the present disclosure is not limited to the mentioned above, and other objects which have not been mentioned above will be clearly understood to those skilled in the art from the following description.

In some implementations, a semiconductor package comprises: a lower semiconductor package; and an upper semiconductor package on the lower semiconductor package. The lower semiconductor package may include: a first substrate; and a dielectric pattern on a top surface of the first substrate. The first substrate may include a plurality of first pads. The dielectric pattern may include a plurality of stepwise openings that expose the first pads. A cross-section of each of the stepwise openings may have a pair of stepwise structures. The stepwise structure may include: a first lateral surface; a second lateral surface; and a first bottom surface that connects the first lateral surface and the second lateral surface to each other. The first lateral surface may be connected to a top surface of the first pad. The second lateral surface may be connected to a top surface of the dielectric pattern. The upper semiconductor package may include a plurality of connection terminals on a lower portion of the upper semiconductor package. The connection terminals may be correspondingly attached to the first pads.

In some implementations, a semiconductor package comprises: a lower semiconductor package; and an upper semiconductor package on the lower semiconductor package. The lower semiconductor package may include a first substrate. The first substrate may include: a plurality of wiring patterns; a plurality of pads on the wiring patterns; and a dielectric pattern that covers the wiring patterns. The dielectric pattern may include: a first opening that exposes the pad; and a second opening on the first opening. The first opening may be closer than the second opening to a top surface of the pad. The first opening may have a first width in a first direction parallel to a top surface of the first substrate. The second opening may have a second width in the first direction. The first width may be less than the second width.

In some implementations, a semiconductor package comprises: a lower semiconductor package; and an upper semiconductor package on the lower semiconductor package. The lower semiconductor package may include: a lower redistribution substrate; an upper redistribution substrate on the lower redistribution substrate; and a logic chip between the lower redistribution substrate and the upper redistribution substrate. The upper redistribution substrate may include: a plurality of dielectric layers; a plurality of wiring patterns in the dielectric layers; a plurality of pads on the wiring patterns; and a dielectric pattern that covers the wiring patterns. The dielectric pattern may include: a first opening that exposes the pad; and a second opening on the first opening. The first opening may be closer than the second opening to a top surface of the pad. A cross-section of each of the first opening and the second opening may have a trapezoidal shape. The first opening may have a first diameter. The second opening may have a second diameter. The second diameter may be greater than the first diameter. The first diameter and the second diameter may increase with increasing distance from the top surface of the pad. The upper semiconductor package may include: a package substrate; and a memory chip on the package substrate.

### BRIEF DESCRIPTION OF THE DRAWINGS

FIG. 1A illustrates a cross-sectional view showing an example of a semiconductor package.

FIG. 1B illustrates an example enlarged view showing section CU1 of FIG. 1A.

FIG. 2 illustrates a cross-sectional view showing an example of a semiconductor package.

FIG. 3 illustrates a cross-sectional view showing an example of a semiconductor package.

FIGS. 4, 5A, 6A, 7A, and 8A illustrate cross-sectional views showing an example of a method of fabricating a semiconductor package.

FIGS. 5B, 6B, 7B, and 8B illustrate example enlarged views showing sections CU2, CU3, CU4, and CU5 of FIGS. 5A, 6A, 7A, and 8A, respectively.

### DETAILED DESCRIPTION

The following will now describe in detail some implementations of the present disclosure with reference to the accompanying drawings.

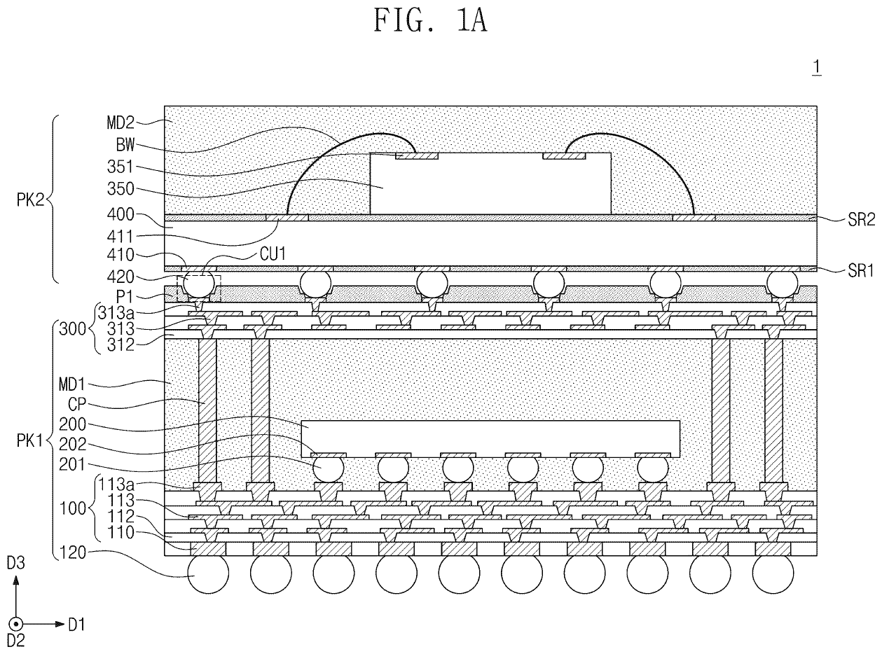

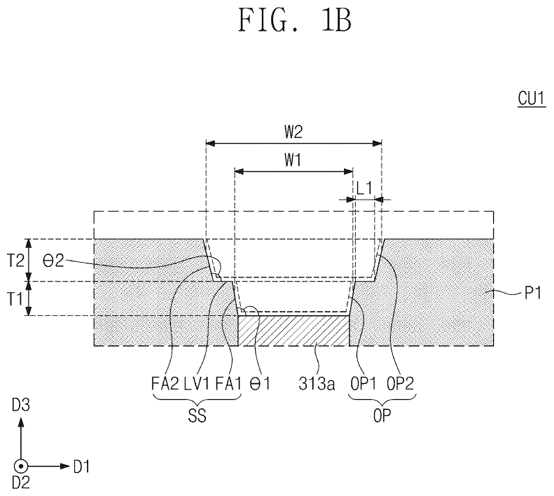

FIG. 1A illustrates a cross-sectional view showing an example of a semiconductor package. FIG. 1B illustrates an example enlarged view showing section CU1 of FIG. 1A. For clarity of the present disclosure, FIG. 1B omits the illustration of a package connection terminal depicted in FIG. 1A.

Referring to FIG. 1A, a semiconductor package 1 may include a first semiconductor package PK1 and a second semiconductor package PK2 on the first semiconductor package PK1. The semiconductor package 1 may have a package-on-package structure. In this description, the first semiconductor package PK1 and the second semiconductor package PK2 may be respectively called a lower semiconductor package PK1 and an upper semiconductor package PK2.

The first semiconductor package PK1 may include a first redistribution substrate 100, a first semiconductor chip 200, a second redistribution substrate 300, and a first molding layer MD1. In this description, the first redistribution substrate 100 and the second redistribution substrate 300 may be respectively called a lower redistribution substrate 100 and an upper redistribution substrate 300.

In this description, a first direction D1 is defined to indicate one direction parallel to a top surface of the first redistribution substrate 100. A second direction D2 may is defined to indicate one direction parallel to the top surface of the first redistribution substrate 100 and orthogonal to the first direction D1. A third direction D3 is defined to indicate one direction perpendicular to the top surface of the first redistribution substrate 100.

The first redistribution substrate 100 may include a plurality of first dielectric layers 112 and a plurality of first redistribution patterns 113 that are stacked on each other.

The first dielectric layers 112 may include an organic material, such as a photo-imageable dielectric (PID). The photo-imageable dielectric may be a polymer. The photo-imageable dielectric material may include, for example, at least one selected from photosensitive polyimide, polybenzoxazole, phenolic polymers, and benzocyclobutene polymers. FIG. 1A depicts a boundary between the first dielectric layers 112, but the present disclosure are not limited thereto. In some implementations, an indistinct interface may be present between neighboring first dielectric layers 112.

The first redistribution patterns 113 may be provided in the first dielectric layers 112. The first redistribution patterns 113 may each have a first via part and a first wire part that are connected into a single unitary piece. The first wire part may be a pattern for horizontal connection in the first redistribution substrate 100. The first via part may be a portion for vertical connection between the first redistribution patterns 113 in the first dielectric layers 112. The first wire part may be provided on the first via part. The first wire part and the first via part may be connected with no interface therebetween. The first wire parts of the first redistribution patterns 113 may be positioned on top surfaces of the first dielectric layers 112. The first via parts of the first redistribution patterns 113 may penetrate the first dielectric layers 112 to come into connection with the first wire parts of underlying first redistribution patterns 113. The first redistribution patterns 113 may include a conductive material. For example, the first redistribution patterns 113 may include copper (Cu).

Although not shown, seed patterns may be disposed on bottom surfaces of the first redistribution patterns 113. For example, the seed patterns may cover bottom surfaces and sidewalls of the first via parts and bottom surfaces of the first wire parts of corresponding first redistribution patterns 113. The seed patterns may include a different material from that of the first redistribution patterns 113. For example, the seed patterns may include copper (Cu), titanium (Ti), or any alloy thereof. In some implementations, the first redistribution patterns 113 may further include a barrier layer that prevents diffusion of materials included in the first redistribution patterns 113. The barrier layer may include titanium nitride (TiN) or tantalum nitride (TaN).

The first redistribution patterns 113 may include first redistribution pads 113a. The first redistribution pads 113a may be portions of an uppermost first redistribution pattern 113 in the first redistribution substrate 100. The first redistribution pads 113a may have their top surfaces that protrude from a top surface of an uppermost first dielectric layer 112. The first redistribution pads 113a may be connected to underlying first redistribution patterns 113.

Under-bump patterns 110 may be provided below a lowermost one of the first dielectric layers 112. The under-bump patterns 110 may be spaced apart from each other in the first direction D1. The under-bump patterns 110 may be connected to the first redistribution patterns 113. For example, the first via part of a lowermost one of the first redistribution patterns 113 may penetrate the first dielectric layer 112 to come into connection with the under-bump pattern 110. The under-bump patterns 110 may be electrically connected through the first redistribution patterns 113 to the first redistribution pads 113a. The under-bump patterns 110 may include a conductive material. For example, the under-bump patterns 110 may include copper (Cu).

The first redistribution substrate 100 may be provided with first external connection terminals 120 on a bottom surface thereof. The first external connection terminals 120 may be correspondingly provided on bottom surfaces of the under-bump patterns 110. The first external connection terminals 120 may be spaced apart from each other in the first direction D1. The first external connection terminals 120 may include a solder material. For example, the first external connection terminals 120 may include tin (Sn), bismuth (Bi), lead (Pb), silver (Ag), or any alloy thereof.

The first semiconductor chip 200 may be disposed on the first redistribution substrate 100. The first semiconductor chip 200 may be, for example, a logic chip. The first semiconductor chip 200 may be, for example, a central processor unit (CPU), a micro processor unit (MPU), a graphic processor unit (GPU), or an application processor (AP). A plurality of first chip pads 202 may be disposed on a bottom surface of the first semiconductor chip 200.

A plurality of first connection terminals 201 may be disposed between the first redistribution substrate 100 and the first semiconductor chip 200. For example, the first connection terminals 201 may be interposed between and in contact with the first redistribution pads 113a and the first chip pads 202. The first semiconductor chip 200 may be electrically connected through the first connection terminals 201 to the first redistribution substrate 100. The first connection terminals 201 may be an alloy that includes at least one selected from tin (Sn), silver (Ag), copper (Cu), nickel (Ni), bismuth (Bi), indium (In), antimony (Sb), and cerium (Ce).

The first molding layer MD1 may be disposed on the first redistribution substrate 100. The first molding layer MD1 may be disposed to cover the top surface of the first redistribution substrate 100 and to also cover lateral and top surfaces of the first semiconductor chip 200. The first molding layer MD1 may include a dielectric material, and the dielectric material may include either a material such as an epoxy molding compound (EMC) or an adhesive material.

The second redistribution substrate 300 may be disposed on the first molding layer MD1. The second redistribution substrate 300 may include second dielectric layers 312, second redistribution patterns 313, and a dielectric pattern P1. The second redistribution patterns 313 may include second redistribution pads 313a. The second redistribution pads 313a may be portions of an uppermost second redistribution pattern 313 in the second redistribution substrate 300. The second redistribution pads 313a may have their top surfaces that protrude from a top surface of the second dielectric layer 312.

The dielectric pattern P1 may be disposed on a top surface of the second redistribution substrate 300. The dielectric pattern P1 may expose the second redistribution pads 313a. The dielectric pattern P1 may be a photo-imageable dielectric (PID) or a solder resist. The dielectric pattern P1 may include at least one selected from acrylic resin, photosensitive phenolic resin, and photosensitive polyimide resin. The dielectric pattern P1 will be further discussed in detail below.

A conductive pillar CP may penetrate the first molding layer MD1 to reside between the first redistribution substrate 100 and the second redistribution substrate 300. A plurality of conductive pillars CP may be disposed spaced apart in the first direction D1 from the first semiconductor chip 200. The conductive pillar CP may be in contact with a portion of the first redistribution pad 113a and the second redistribution pattern 313. For example, the conductive pillar CP may be electrically connected to the first redistribution pad 113a and the second redistribution pattern 313.

The second semiconductor package PK2 may be disposed on the second redistribution substrate 300. The second semiconductor package PK2 may include a first package substrate 400, a second semiconductor chip 350, and a second molding layer MD2.

The first package substrate 400 may be, for example, a printed circuit board (PCB). Alternatively, although not shown, the first package substrate 400 may have a structure in which at least one dielectric layer and at least one wiring layer are alternately stacked. The first package substrate 400 may include a first solder resist pattern SR1 on a bottom surface thereof and a second solder resist pattern SR2 on a top surface thereof. The first package substrate 400 may include a plurality of first package substrate pads 411 on the top surface thereof and a plurality of second package substrate pads 410 on the bottom surface thereof.

The second semiconductor chip 350 may be disposed on the first package substrate 400. The second semiconductor chip 350 may be of a different type from the first semiconductor chip 200. For example, the second semiconductor chip 350 may be a memory chip, such as DRAM or NAND Flash. A second chip pad 351 disposed on one surface of the second semiconductor chip 350 may be connected through a bonding wire BW to the first package substrate pad 411 of the first package substrate 400.

The second molding layer MD2 may be disposed on the first package substrate 400. The second molding layer MD2 may cover the top surface of the first package substrate 400 and may also cover lateral and top surfaces of the second semiconductor chip 350. The second molding layer MD2 may include a material substantially the same as or similar to that of the first molding layer MD1.

One or more package connection terminals 420 may be provided between the first semiconductor package PK1 and the second semiconductor package PK2. The package connection terminals 420 may be attached to the second redistribution pads 313a to contact the second package substrate pads 410. The package connection terminals 420 may electrically connect the first semiconductor package PK1 and the second semiconductor package PK2 to each other. The package connection terminals 420 may include a metallic material substantially the same as or similar to that of the first external connection terminals 120. For example, the package connection terminals 420 may include tin (Sn), bismuth (Bi), lead (Pb), silver (Ag), or any alloy thereof.

Referring to FIGS. 1A and 1B, the dielectric pattern P1 may include stepwise openings OP. The stepwise openings OP may expose the top surface of the second redistribution pad 313a. Each of the stepwise openings OP may have a cross-section that includes a pair of stepwise structures SS. The stepwise structure SS may include a first lateral surface FA1, a second lateral surface FA2, and a first bottom surface LV1 that connects the first lateral surface FA1 and the second lateral surface FA2 to each other. The first lateral surface FA1 may be connected to the top surface of the second redistribution pad 313a. The second lateral surface FA2 may be connected to a top surface of the dielectric pattern P1. In this case, the first lateral surface FA1 and the second lateral surface FA2 may have an inclined shape. For example, a first angle θ1 may be made between the first lateral surface FA1 and the top surface of the second redistribution pad 313a. The first angle θ1 may range from about 135° to about 150°. A second angle θ2 may be made between the second lateral surface FA2 and the first bottom surface LV1. The second angle θ2 may have substantially the same range as that of the first angle θ1. For example, the second angle θ2 may range of about 135° to about 150°. In some implementations, the second angle θ2 may be greater than the first angle θ1. For example, the second angle θ2 may be about 5° to about 15° greater than the first angle θ1. The first bottom surface LV1 may have a first length L1 in the first direction D1. The first length L1 may range from about 4 μm to about 6 μm.

Each of the stepwise openings OP may include a first opening OP1 and a second opening OP2 that is connected to and provided on the first opening OP1. In this case, the first opening OP1 may be a region where the first lateral surfaces FA1 face each other which are included in the pair of stepwise structures SS on the second redistribution pad 313a. The second opening OP2 may be a region where the second lateral surfaces FA2 face each other which are included in the pair of stepwise structures SS on the first opening OP1.

The first opening OP1 may be closer than the second opening OP2 to the second redistribution pads 313a. For example, the second opening OP2 may closer than the first opening OP1 to the second package substrate pad 410. The first opening OP1 and the second opening OP2 may have their cross-sections each of which has a trapezoidal shape.

The first opening OP1 may have a first width W1 in the first direction D1, and the second opening OP2 may have a second width W2 in the first direction D1. In this description, the first width W1 and the second width W2 may be respectively called a first diameter and a second diameter. The first width W1 may be less than the second width W2. The first width W1 may be about 80% to about 95% of the second width W2. For example, the first width W1 may range from about 190 μm to about 210 μm, and the second width W2 may range from about 210 μm to about 225 μm. The first width W1 and the second width W2 may increase with increasing distance in the third direction D3 from the second redistribution pad 313a.

In addition, a minimum value of the first width W1 may be the same as or less than a diameter of the top surface of the second redistribution pad 313a. A maximum value of the first width W1 may be greater than the diameter of the top surface of the second redistribution pad 313a. For example, the minimum value of the first width W1 may correspond to a diameter of a lowermost portion of the first opening OP1, and the maximum value of the first width W1 may corresponding to a diameter of an uppermost portion of the first opening OP1. The second width W2 of the second opening OP2 may be greater than the diameter of the top surface of the second redistribution pad 313a.

The first opening OP1 may have a first depth T1 in the third direction D3, and the second opening OP2 may have a second depth T2 in the third direction D3. The first depth T1 may correspond to a length in the third direction D3 from the top surface of the second redistribution pad 313a to the first bottom surface LV1. The second depth T2 may correspond to a length in the third direction D3 from the first bottom surface LV1 to the top surface of the dielectric pattern P1. In some implementations, the first depth T1 and the second depth T2 may be substantially the same as each other. For example, the first depth T1 and the second depth T2 may range from about 13 μm to about 17 μm.

The semiconductor package 1 may include the dielectric pattern P1 formed in the lower semiconductor package PK1. In such a case, the dielectric pattern P1 may have the stepwise opening OP whose cross-section includes a pair of stepwise structures SS with the first lateral surface FA1, the second lateral surface FA2, and the first bottom surface LV1 that connects the first lateral surface FA1 and the second lateral surface FA2 to each other. The first lateral surface FA1 and the second lateral surface FA2 may have an inclined shape. Accordingly, even though a alignment difference (e.g., misalignment) of ten or more percents is provided between the package connection terminal 420 included in a lower end of the upper semiconductor package PK2 and the second redistribution pad 313a included in the lower semiconductor package PK1, the package connection terminal 420 may slide along inclined sides of the first and second lateral surfaces FA1 and FA2 to be stably attached to the second redistribution pad 313a. When an inclination angle of the second lateral surface FA2 is greater than that of the first lateral surface FA1, a sufficiently sized opening may be obtained. Thus, the package connection terminal 420 may be stably attached to the second redistribution pad 313a to increase a bonding force between the upper semiconductor package PK2 and the lower semiconductor package PK1. As a result, the semiconductor package 1 may increase in structural stability.

According to the present disclosure, it is not needed to increase a thickness of the dielectric pattern P1 in comparison with a case where an opening does not have a stepwise inclined lateral surface but has a single inclined surface. For example, to allow the package connection terminal 420 to contact the second redistribution pad 313a when a misalignment occurs in a case where an opening has a single inclined surface, it may be required that the opening have a diameter greater than that of the top surface of the second redistribution pad 313a and that the inclined surface have a satisfied angle. In this case, when the dielectric pattern P1 has no increase in thickness, the opening may have an increased size without securing a sufficiently long inclined surface, and thus the package connection terminal 420 may be in contact not with the second redistribution pad 313a but with an inappropriate location. In contrast, according to the present disclosure, because the second diameter W2 is greater than the diameter of the second redistribution pad 313a, and because the first diameter W1 is the same as or less than the diameter of the second redistribution pad 313a, the package connection terminal 420 may be stably attached to the second redistribution pad 313a along a stepwise inclined surface even without increasing the thickness of the dielectric pattern P1.

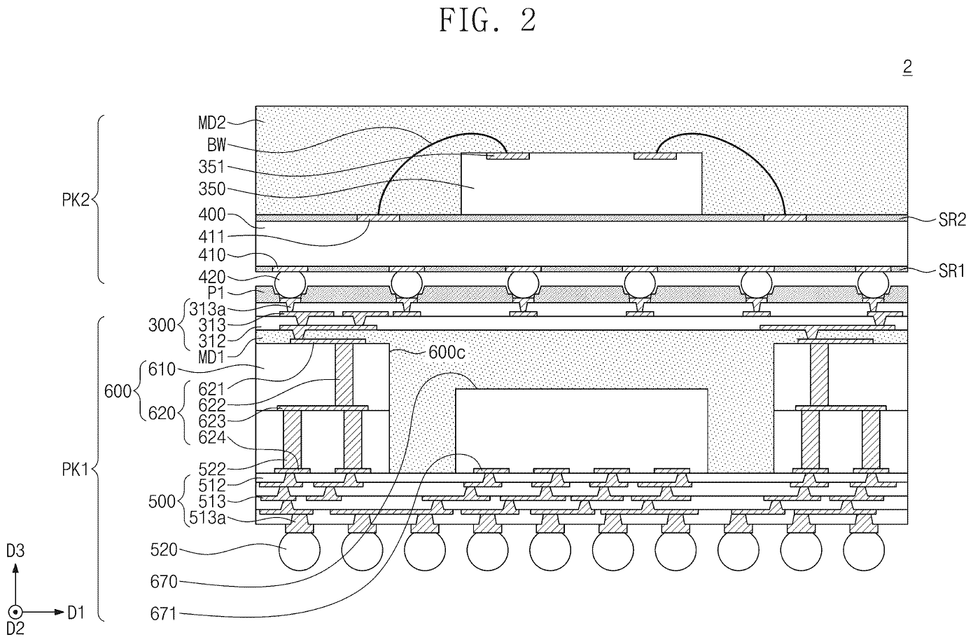

FIG. 2 illustrates a cross-sectional view showing an example of a semiconductor package. Omission will be made to avoid a repetitive explanation discussed with reference to FIGS. 1A and 1B.

Referring to FIG. 2, a semiconductor package 2 may include a first semiconductor package PK1 and a second semiconductor package PK2 on the first semiconductor package PK1. The first semiconductor package PK1 may include a third redistribution substrate 500, a third semiconductor chip 670, and a connection substrate 600.

The third redistribution substrate 500 may include a plurality of third dielectric layers 512 and a plurality of third redistribution patterns 513 that are stacked on each other. The third redistribution patterns 513 may be provided in the third dielectric layer 512. The third redistribution patterns 513 may include third redistribution pads 513a. The third redistribution pads 513a may be portions of a lowermost third redistribution pattern 513 of the third redistribution substrate 500. The third redistribution pads 513a may be connected to overlying third redistribution patterns 513.

The third redistribution substrate 500 may be provided with second external connection terminals 520 on a bottom surface thereof. The second external connection terminals 520 may be correspondingly provided on bottom surfaces of the third redistribution pads 513a. The second external connection terminals 520 may be spaced apart from each other in the first direction D1. The second external connection terminals 520 may include a solder material. For example, the second external connection terminals 520 may include tin (Sn), bismuth (Bi), lead (Pb), silver (Ag), or any alloy thereof.

The third semiconductor chip 670 may be disposed on the third redistribution substrate 500. The third semiconductor chip 670 may be, for example, a logic chip. The third semiconductor chip 670 may be, for example, a central processor unit (CPU), a micro processor unit (MPU), a graphic processor unit (GPU), or an application processor (AP).

A plurality of third chip pads 671 may be disposed on a bottom surface of the third semiconductor chip 670. The third chip pad 671 may be connected to a portion of an uppermost third redistribution pattern 513 of the third redistribution substrate 500.

The connection substrate 600 may be disposed on the third redistribution substrate 500. The connection substrate 600 may be disposed apart in the first direction D1 from the third semiconductor chip 670. For example, the connection substrate 600 may have at its center a cavity 600c that penetrates therethrough. For example, the connection substrate 600 may be manufactured by forming the cavity 600c in a printed circuit board (PCB). The connection substrate 600 may include base layers 610 and a conductive structure 620.

Each of the base layers 610 may include at least one selected from a thermosetting resin such as phenol resin and epoxy resin, a thermoplastic resin such as polyimide, a dielectric material in which a thermosetting or thermoplastic resin is impregnated in an inorganic filler and/or glass fiber (glass cloth or glass fabric). For example, the base layer 610 may include at least one selected from prepreg, Ajinomoto build-up film (ABF), flame retardant 4 (FR4), tetra-functional epoxy, polyphenylene ether, bismaleimide triazine (BT), epoxy/polyphenylene oxide, Thermount™, cyanate ester, polyimide, and liquid crystal polymer.

The conductive structure 620 may include a first connection pad 624, a second connection pad 621, a connection line 623, and a connection via 622.

The first connection pad 624 may be provided on a bottom surface of the connection substrate 600. The second connection pad 621 may be connected to a portion of the third redistribution pattern 513. The connection line 623 may be interposed between the base layers 610. A plurality of connection vias 622 may penetrate the base layers 610 to come into connection with the connection line 623. The second connection pad 621 may be disposed on a top surface of the connection substrate 600 and connected to one of the connection vias 622. The second connection pad 621 may be electrically connected to the first connection pad 624 through the connection vias 622 and the connection lines 623. The second connection pad 621 and the first connection pad 624 may differ from each other in terms of the number or arrangement. The second connection pad 621 may be connected to a portion of the second redistribution pattern 313. The first connection pad 624, the second connection pad 621, and the connection line 623 may include at least one selected from electrolytically deposited (ED) copper foil, rolled-annealed (RA) copper foil, stainless steel foil, aluminum foil, ultra-thin copper foil, sputtered copper, and copper alloys. The connection via 622 may include at least one selected from copper, nickel, stainless steel, and beryllium copper.

A first molding layer MD1 may be disposed on the third redistribution substrate 500. The first molding layer MD1 may fill gap between the third semiconductor chip 670 and an inner lateral surface of the connection substrate 600. The first molding layer MD1 may cover a top surface of the third semiconductor chip 670 and the top surface of the connection substrate 600.

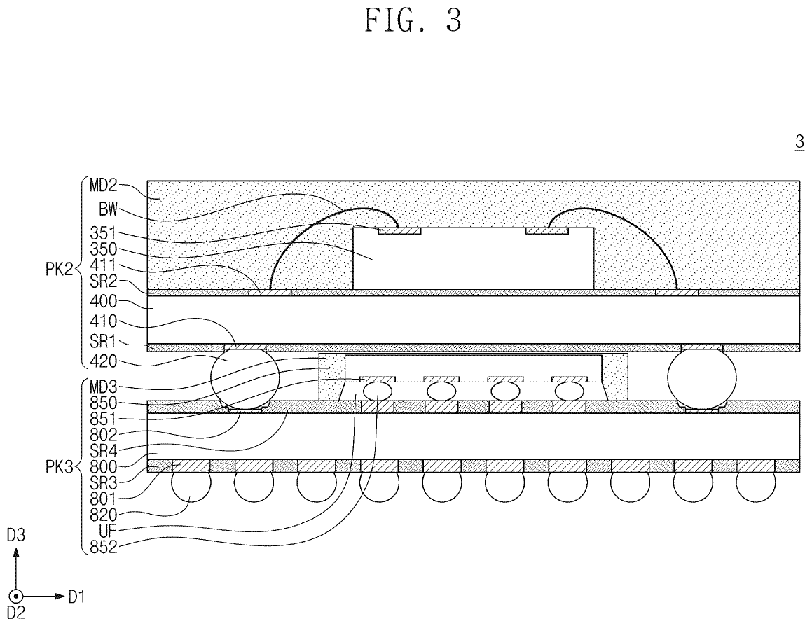

FIG. 3 illustrates a cross-sectional view showing an example of a semiconductor package. Omission will be made to avoid a repetitive explanation of those discussed with reference to FIGS. 1A and 1B.

Referring to FIG. 3, a semiconductor package 3 may include a second semiconductor package PK2 and a third semiconductor package PK3.

The third semiconductor package PK3 may include a second package substrate 800, a fourth semiconductor chip 850, and a third molding layer MD3.

The second package substrate 800 may be, for example, a printed circuit board (PCB). Alternatively, although not shown, the second package substrate 800 may have a structure in which at least one dielectric layer and at least one wiring layer are alternately stacked. The second package substrate 800 may include a third solder resist pattern SR3 on a bottom surface thereof and a fourth solder resist pattern SR4 on a top surface thereof. The second package substrate 800 may include a plurality of third package substrate pads 802 on the top surface thereof and a plurality of fourth package substrate pads 801 on the bottom surface thereof.

A plurality of third external connection terminals 820 may be correspondingly disposed on the fourth package substrate pads 801. The third external connection terminals 820 may include a metallic material substantially the same as or similar to that of the first external connection terminals 120. For example, the third external connection terminals 820 may include tin (Sn), bismuth (Bi), lead (Pb), silver (Ag), or any alloy thereof.

As discussed above, the third solder resist pattern SR3 and the fourth solder resist pattern SR4 may be respectively disposed on the bottom surface and the top surface of the second package substrate 800. The fourth solder resist pattern SR4 may expose the third package substrate pads 802. The fourth solder resist pattern SR4, which expose the third package substrate pad 802 in contact with a package connection terminal 420 which will be discussed below, may have a portion whose shape is substantially the same as that of the dielectric pattern P1 discussed in FIG. 1B.

The fourth semiconductor chip 850 may be disposed on the second package substrate 800. The fourth semiconductor chip 850 may be, for example, a logic chip. The fourth semiconductor chip 850 may be, for example, a central processor unit (CPU), a micro processor unit (MPU), a graphic processor unit (GPU), or an application processor (AP). A plurality of fourth chip pads 851 may be disposed on a bottom surface of the fourth semiconductor chip 850.

A plurality of second connection terminals 852 may be provided between the second package substrate 800 and the fourth semiconductor chip 850. For example, the second connection terminals 852 may be interposed between and in contact with the fourth chip pads 851 and ones of the third package substrate pads 802. The second connection terminals 852 may include a metallic material substantially the same as or similar to that of the first external connection terminals 120 discussed in FIG. 1A.

An underfill pattern UF may be provided between the second package substrate 800 and the fourth semiconductor chip 850. The underfill pattern UF may fill a space between the second package substrate 800 and the fourth semiconductor chip 850 and may surround a lateral surface of each of the second connection terminals 852. The underfill pattern UF may include, for example, an epoxy resin.

A third molding layer MD3 may be provided to cover a portion of the top surface of the second package substrate 800, lateral and top surfaces of the fourth semiconductor chip 850, and a lateral surface of the underfill pattern UF. In some implementations, differently from that shown, the third molding layer MD3 may cover an entirety of the top surface of the second package substrate 800. The third molding layer MD3 may include a dielectric material, and the dielectric material may include either a material such as an epoxy molding compound (EMC) or an adhesive material.

A package connection terminal 420 may be disposed between the second semiconductor package PK2 and the third semiconductor package PK3. The package connection terminal 420 may be disposed spaced apart in the first direction D1 from the fourth semiconductor chip 850. The package connection terminal 420 may be in contact with the second package substrate pad 410 and the third package substrate pad 802. The package connection terminal 420 may electrically connect the second semiconductor package PK2 to the third semiconductor package PK3.

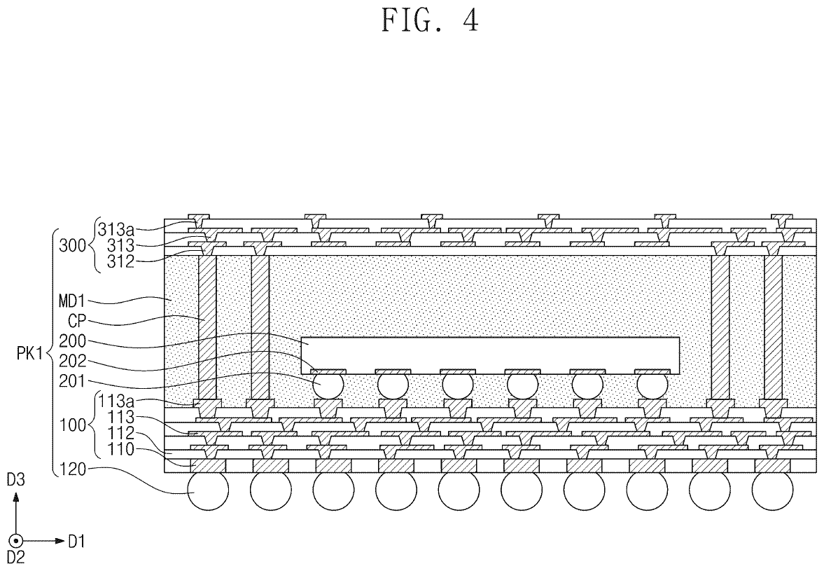

FIGS. 4, 5A, 6A, 7A, and 8A illustrate cross-sectional views showing an example of a method of fabricating a semiconductor package.

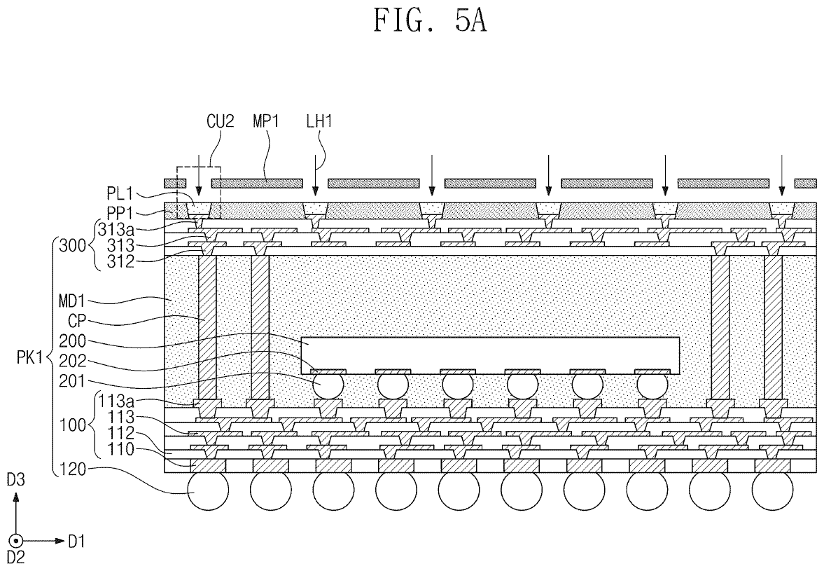

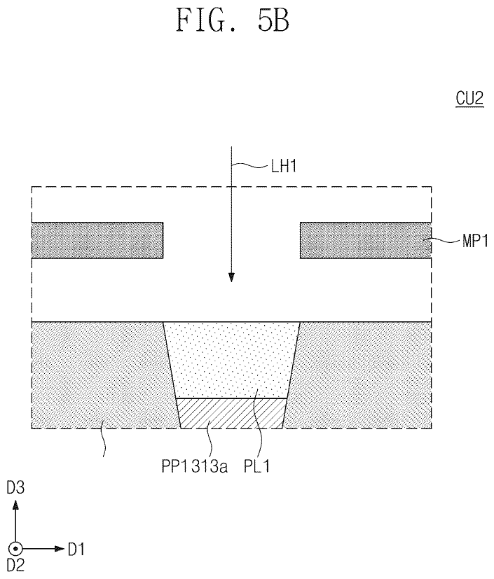

FIGS. 5B, 6B, 7B, and 8B illustrate example enlarged views showing sections CU2, CU3, CU4, and CU5 of FIGS. 5A, 6A, 7A, and 8A, respectively.

Referring to FIG. 4, a first semiconductor package PK1 may be provided. The first semiconductor package PK1 may include a first redistribution substrate 100, a first semiconductor chip 200, a first molding layer MD1, and a second redistribution substrate 300.

Referring to FIGS. 5A and 5B, a dielectric layer PP1 may be formed on a top surface of the second redistribution substrate 300. The dielectric layer PP1 may cover second redistribution pads 313a. The dielectric layer PP1 may be formed by using a positive photo-imageable material.

Afterwards, a first exposure process may be performed on the dielectric layer PPL. The first exposure process may include placing a first mask pattern MP1 on a region of the dielectric layer PP1 other than a region through which the second redistribution pads 313a will be exposed, irradiating a first light LH1 to the dielectric layer PP1 and the first mask pattern MP1, and removing the first mask pattern MP1. The first light LH1 irradiated to the dielectric layer PP1 and the first mask pattern MP1 may have a wavelength of about 365 nm to about 436 nm.

The irradiation of the first light LH1 to the dielectric layer PP1 and the first mask pattern MP1 may form a first exposure region PL1. The first exposure region PL1 may be formed on a partial region of the dielectric layer PP1 where the first mask pattern MP1 is not disposed.

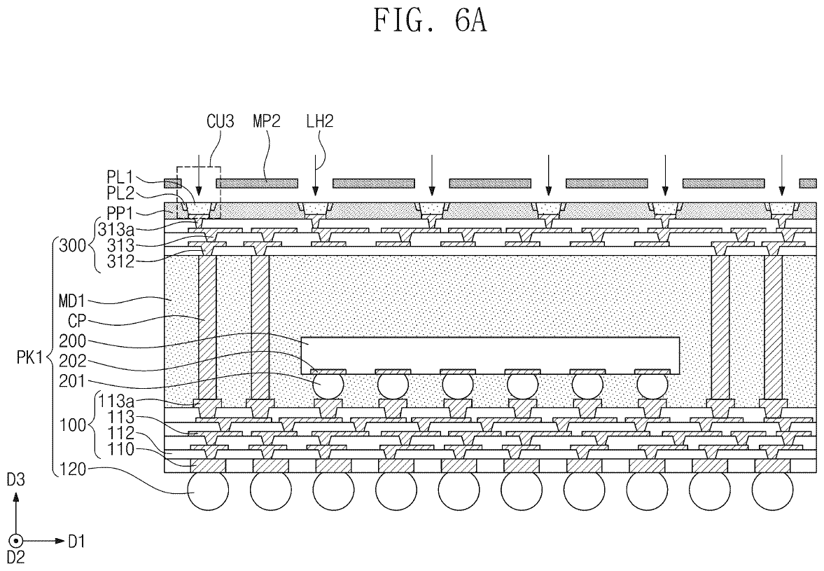

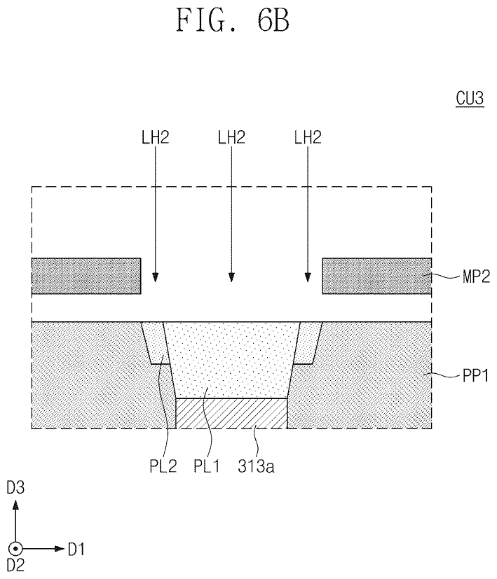

Referring to FIGS. 6A and 6B, a second exposure process may be performed on the dielectric layer PPL. The second exposure process may include placing a second mask pattern MP2 on a region of the dielectric layer PP1 except for the first exposure region PL1, irradiating a second light LH2 to the dielectric layer PP1 and the second mask pattern MP2, and removing the second mask pattern MP2. The second light LH2 irradiated to the dielectric layer PP1 and the second mask pattern MP2 may have a wavelength of about 365 nm to about 436 nm.

An interval in the first direction D1 between the second mask patterns MP2 may be greater than an interval in the first direction D1 between the first mask patterns MP1 depicted in FIG. 5A. For example, the second mask pattern MP2 may partially expose a top surface of the dielectric layer PP1. As a result, a range of the second light LH2 irradiated to the dielectric layer PP1 in the second exposure process may be greater than a range of the first light LH1 irradiated to the dielectric layer PP1 in the first exposure process.

The progress of the second exposure process may form a second exposure region PL2. The second exposure region PL2 may be formed on a partial region of the dielectric layer PP1 where the second mask pattern MP2 is not disposed.

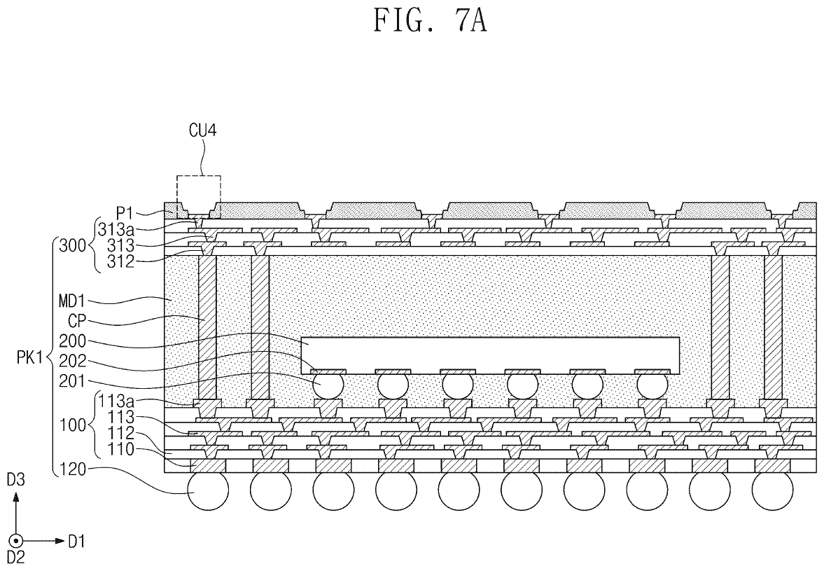

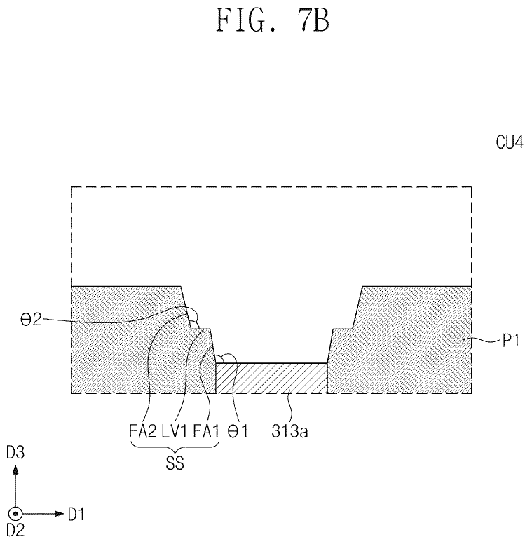

Referring to FIGS. 7A and 7B, a development process and a thermal curing may be sequentially performed on the dielectric layer PP1 discussed in FIGS. 5A to 6B. For example, the first exposure region PL1 formed in FIG. 5A may be removed, and the second exposure region PL2 formed in FIG. 6B may be removed. The removal of the first exposure region PL1 and the second exposure region PL2 may form a dielectric pattern P1. For example, the dielectric pattern P1 may include a stepwise structure SS having a first lateral surface FA1, a second lateral surface FA2, and a first bottom surface LV1. A first angle θ1 may be made between the first lateral surface FA1 and the second redistribution pad 313a. The first angle θ1 may range from about 135° to about 150°. A second angle θ2 may be made between the second lateral surface FA2 and the first bottom surface LV1. The first angle θ1 and the second angle θ2 may be formed to have a range of about 135° to about 150°. In the process discussed in FIGS. 6A and 6B, when the second light LH2 has a composite wavelength (i-line, h-line, and g-line), the second angle θ2 may be formed greater than the first angle θ1.

Although not shown, a post-development bake (PDB) may be formed after the development process. The post-development bake (PDB) process may be performed at a temperature less than that of a thermal curing process which will be discussed below. For example, the post-development bake (PDB) process may be performed at about 120° C. to about 130° C. The progress of the post-development bake (PDB) process may increase the second angle θ2.

Thereafter, a thermal curing process may be performed on the dielectric pattern P1. The thermal curing process may cure the dielectric pattern P1.

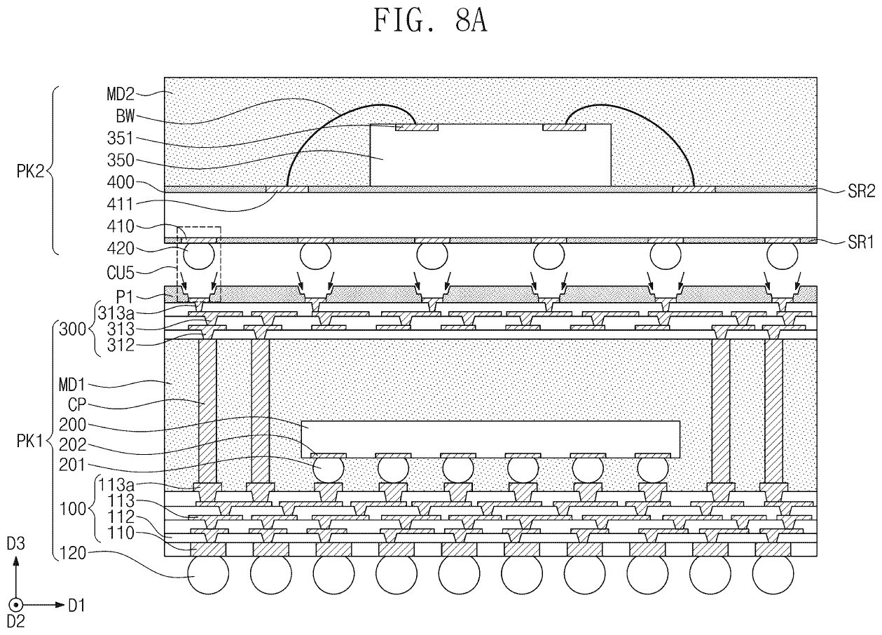

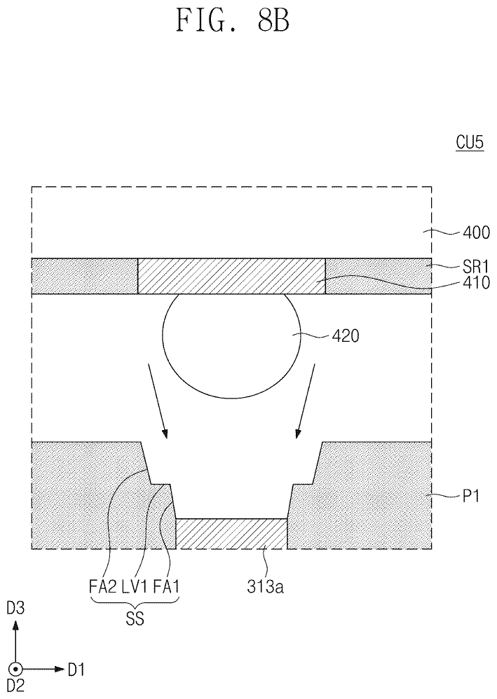

Referring to FIGS. 8A and 8B, a second semiconductor package PK2 may be provided on the first semiconductor package PK1. The second semiconductor package PK2 may include a first package substrate 400, a second semiconductor chip 350, a second molding layer MD2, and package connection terminals 420.

For example, the second semiconductor package PK2 may move along the third direction D3 to become adjacent to the first semiconductor package PK1. In this step, the package connection terminal 420 may be attached to a top surface of the second redistribution pad 313a exposed by the dielectric pattern P1. Even when a partial misalignment is present between the package connection terminal 420 and the second redistribution pad 313a, the package connection terminal 420 may slide along the stepwise structure SS of the dielectric pattern P1 to contact the second redistribution pad 313a. As the first semiconductor package PK1 and the second semiconductor package PK2 are connected through the package connection terminal 420, a semiconductor package 1 may be eventually fabricated.

In a method of fabricating a semiconductor package, the first and second exposure processes may be sequentially performed on a photo-imageable material so as to form the stepwise structure SS of the dielectric pattern P1. In this step, it may be possible to variously change a rising speed of temperature and an irradiation range of light used for the first and second exposure processes performed on the photo-imageable material. For example, an increase in rising speed of temperature may reduce values of the first angle θ1 and the second angle θ2. As a result, the stepwise structure SS included in the dielectric pattern P1 may be formed to have a shape that is variously changed to coincide with diverse implementations of a semiconductor package.

In addition, the dielectric pattern P1 may be formed by using a positive photo-imageable material. A section where no mask pattern is disposed on a region on which a positive photo-imageable material may be exposed to light and removed in the first and second exposure processes, and therefore there may be an increase in resolution in the first and second exposure processes. In conclusion, the stepwise structure SS included in the dielectric pattern P1 may be elaborately formed to have a shape to coincide with various implementations of a semiconductor package.

A semiconductor package may include a lower semiconductor package and an upper semiconductor package on the lower semiconductor package. A dielectric pattern included in the lower semiconductor package may have an opening whose cross-section includes a stepwise structure with a first lateral surface, a second lateral surface, and a first bottom surface that connects the first lateral surface and the second lateral surface to each other. The first lateral surface and the second lateral surface may have an inclined shape. Thus, a connection terminal included in a lower end of the upper semiconductor package may slide along the inclined shape of the first and second lateral surfaces to be stably attached to a pad of the lower semiconductor package, which may result in an increase in structural stability of the semiconductor package.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The aforementioned description provides some implementations for explaining the present disclosure. Therefore, the present disclosure are not limited to the implementations described above, and it will be understood by one of ordinary skill in the art that variations in form and detail may be made therein without departing from the spirit and essential features of the present disclosure.

What is claimed is:

1. A semiconductor package, comprising:
a lower semiconductor package; and
an upper semiconductor package on the lower semiconductor package,
wherein the lower semiconductor package includes:
a first substrate; and
a dielectric pattern on a top surface of the first substrate,
wherein the first substrate includes a plurality of first pads,
wherein the dielectric pattern includes a plurality of stepwise openings that expose the plurality of first pads,
wherein a cross-section of each stepwise opening of the plurality of stepwise openings has a pair of stepwise structures,
wherein each stepwise structure of the pair of stepwise structures includes:
a first lateral surface;
a second lateral surface; and
a first bottom surface that connects the first lateral surface with the second lateral surface,
wherein the first lateral surface is connected with a top surface of a first pad of the plurality of first pads,
wherein the second lateral surface is connected with a top surface of the dielectric pattern,
wherein the upper semiconductor package includes a plurality of connection terminals on a lower portion of the upper semiconductor package,
wherein the plurality of connection terminals are respectively attached to the plurality of first pads.

2. The semiconductor package of claim 1, wherein
a first angle is between the first lateral surface and the top surface of the first pad, and
the first angle is in a range of 1350 to 150°.

3. The semiconductor package of claim 2, wherein
a second angle is between the first lateral surface and the first bottom surface, and
the second angle is in a range of 1350 to 150°.

4. The semiconductor package of claim 1, wherein the dielectric pattern includes one of a photo-imagable dielectric (PID) or a solder resist.

5. The semiconductor package of claim 1, wherein the upper semiconductor package includes a second pad on a lower portion of the upper semiconductor package, and
wherein a connection terminal is in contact with the first pad and the second pad.

6. The semiconductor package of claim 1,
wherein the lower semiconductor package includes:
a second substrate below the first substrate; and
a first semiconductor chip on the second substrate, the first semiconductor chip being between the first substrate and the second substrate,
wherein the upper semiconductor package includes:
a package substrate; and
a second semiconductor chip on the package substrate, and
wherein the first semiconductor chip and the second semiconductor chip are different types of semiconductor chips.

7. The semiconductor package of claim 6, wherein
the first semiconductor chip is a logic chip, and
the second semiconductor chip is a memory chip.

8. A semiconductor package, comprising:
a lower semiconductor package; and
an upper semiconductor package on the lower semiconductor package,
wherein the lower semiconductor package includes a first substrate,
wherein the first substrate includes:
a plurality of wiring patterns;
a plurality of pads on the plurality of wiring patterns; and
a dielectric pattern that covers the plurality of wiring patterns,
wherein the dielectric pattern includes:
a first opening that exposes a pad of the plurality of pads; and
a second opening on the first opening,
wherein the first opening is closer than the second opening to a top surface of the pad,
wherein the first opening has a first width in a first direction, the first direction being parallel to a top surface of the first substrate,
wherein the second opening has a second width in the first direction,
wherein the first width is less than the second width.

9. The semiconductor package of claim 8, wherein the lower semiconductor package includes:
a second substrate below the first substrate; and
a first semiconductor chip on the second substrate, the first semiconductor chip being between the first substrate and the second substrate,
wherein the first width increases as a distance from the pad to the first opening in a second direction increases, the second direction being perpendicular to the top surface of the first substrate.

10. The semiconductor package of claim 9, wherein the second width increases as a distance from the pad to the second opening in the second direction increases.

11. The semiconductor package of claim 8, wherein the first width is 80% to 95% of the second width.

12. The semiconductor package of claim 8, wherein
the first width is in a range of 190 μm to 210 μm, and
the second width is in a range of 210 μm to 225 μm.

13. The semiconductor package of claim 9, wherein
the first opening has a first depth in the second direction,
the second opening has a second depth in the second direction, and
the first depth and the second depth are in a range of 13 μm to 17 μm.

14. The semiconductor package of claim 8, wherein the dielectric pattern includes one of a photo-imageable dielectric (PID) or a solder resist.

15. The semiconductor package of claim 8, wherein the upper semiconductor package includes:
a package substrate;
a second semiconductor chip on the package substrate; and
a plurality of connection terminals on a bottom surface of the package substrate,
wherein the plurality of connection terminals are respectively in contact with the plurality of pads.

16. A semiconductor package, comprising:
a lower semiconductor package; and
an upper semiconductor package on the lower semiconductor package,
wherein the lower semiconductor package includes:
a lower redistribution substrate;
an upper redistribution substrate on the lower redistribution substrate; and
a logic chip between the lower redistribution substrate and the upper redistribution substrate,
wherein the upper redistribution substrate includes:
a plurality of dielectric layers;
a plurality of wiring patterns in the plurality of dielectric layers;
a plurality of pads on the plurality of wiring patterns; and
a dielectric pattern that covers the plurality of wiring patterns,
wherein the dielectric pattern includes:
a first opening that exposes a pad of the plurality of pads; and
a second opening on the first opening,
wherein the first opening is closer than the second opening to a top surface of the pad,
wherein a cross-section of each opening of the first opening and the second opening has a trapezoidal shape,
wherein the first opening has a first diameter,
wherein the second opening has a second diameter,
wherein the second diameter is greater than the first diameter,
wherein the first diameter increases as a distance from the top surface of the pad to the first opening increases,
wherein the second diameter increases as a distance from the top surface of the pad to the second opening increases, and
wherein the upper semiconductor package includes:
a package substrate; and
a memory chip on the package substrate.

17. The semiconductor package of claim 16, wherein the dielectric pattern includes one of a photo-imageable dielectric (PID) or a solder resist.

18. The semiconductor package of claim 16, comprising a connection substrate on a top surface of the lower redistribution substrate,
wherein the connection substrate defines a cavity, and
wherein the logic chip is in the cavity.

19. The semiconductor package of claim 16, comprising:
a molding layer that covers the lower redistribution substrate; and
a conductive pillar that extends through the molding layer and connects the lower redistribution substrate with the upper redistribution substrate,
wherein the conductive pillar is spaced apart in a first direction from the logic chip, the first direction being parallel to a top surface of the lower redistribution substrate.

20. The semiconductor package of claim 16, wherein the first diameter is 80% to 95% of the second diameter.
